(19) United States
(12) Patent Application Publication
(10) Pub. No.: US 2025/0187843 A1
(43) Pub. Date: Jun. 12, 2025

(54) Transport Facility

(71) Applicant: Daifuku Co., Ltd., Osaka-shi (JP)

(72) Inventors: Daisuke Ogawa, Hinocho (JP); Hiroshi Otsuka, Hinocho (JP); Tadashi Nishikawa, Hinocho (JP); Kenshin Hashiguchi, Hinocho (JP); Yuya Hirao, Hinocho (JP); Daichi Tomida, Hinocho (JP); Kosuke Kimura, Hinocho (JP)

(21) Appl. No.: 18/975,995

(22) Filed: Dec. 10, 2024

(30) Foreign Application Priority Data
Dec. 12, 2023 (JP) 2023-209526

(51) Int. Cl. B65G 43/02

(52) U.S. Cl. CPC B65G 43/02

(57) ABSTRACT

A transport facility includes a transport vehicle that transports a transport article along a movement path, a movable object including a communication device that performs wireless communication with the transport vehicle being within a communication range and being movable separately from the transport vehicle, and a movable object controller that controls the movable object. The movable object controller causes, in response to determining that the transport vehicle is faulty, the movable object to be within the communication range of the transport vehicle and causes the communication device to transmit, to the transport vehicle, a recovery command for recovery of the transport vehicle.

### CROSS-REFERENCE TO RELATED APPLICATION

This application claims priority to Japanese Patent Application No. 2023-209526 filed Dec. 12, 2023, the disclosure of which is hereby incorporated by reference in its entirety.

### BACKGROUND OF THE INVENTION

### Field of the Invention

The present invention relates to a transport facility including a transport vehicle that transports a transport article along a movement path.

### Description of Related Art

Japanese Unexamined Patent Application Publication No. 2011-166671 (hereafter referred to as JP No. 2011-166671) describes a transport facility including a transport vehicle (12) that transports a transport article, a transport vehicle controller (18) that controls the transport vehicle (12), and a wireless communicator that allows communication between the transport vehicle (12) and the transport vehicle controller (18). Reference signs in parentheses used in describing the background are the reference signs in JP No. 2011-166671.

The wireless communicator includes multiple wireless transmitter-receivers (8) that perform wireless communication with the transport vehicle (12). The multiple wireless transmitter-receivers (8) are arranged in a distributed manner. The transport vehicle (12) travels while switching, based on its position, the wireless transmitter-receiver (8) with which the transport vehicle (12) performs wireless communication.

In the transport facility described above, the transport vehicle (12) may have a fault and stop. In this case, the transport vehicle controller (18) may transmit a recovery command, such as a command to restart the controller in the transport vehicle (12), to the transport vehicle (12) through the wireless transmitter-receivers (8). However, the transport vehicle (12) may not appropriately receive the recovery command depending on, for example, the communication environment surrounding the transport vehicle (12).

### SUMMARY OF THE INVENTION

One or more aspects described herein are directed to a transport facility in which a faulty transport vehicle can be recovered with higher possibility.

In response to the above, a transport facility includes a transport vehicle that transports a transport article along a movement path, a movable object including a communication device that performs wireless communication with the transport vehicle being within a communication range and being movable separately from the transport vehicle, and a movable object controller that controls the movable object. The movable object controller causes, in response to determining that the transport vehicle is faulty, the movable object to be within the communication range of the transport vehicle and causes the communication device to transmit, to the transport vehicle, a recovery command for recovery of the transport vehicle.

In this structure, the movable object moves separately from the transport vehicle, and can thus appropriately move into the communication range of any faulty transport vehicle. This allows the movable object to transmit the recovery command to the transport vehicle, with lower likelihood of being affected by, for example, the communication environment surrounding the transport vehicle. Thus, the faulty transport vehicle can be recovered with higher possibility.

### BRIEF DESCRIPTION OF THE DRAWINGS

FIG. 1 is a plan view of a transport facility according to an embodiment.

FIG. 2 is a perspective view of a transport vehicle included in the transport facility according to the embodiment.

FIG. 3 is a block diagram of the transport facility according to the embodiment.

FIG. 4 is a diagram of a movable object transmitting a recovery command to the transport vehicle.

FIG. 5 is a diagram describing an example tracking process.

FIG. 6 is a diagram describing an example towing process.

FIG. 7 is a diagram describing an example alternative transport process.

### DESCRIPTION OF THE INVENTION

### 1. First Embodiment

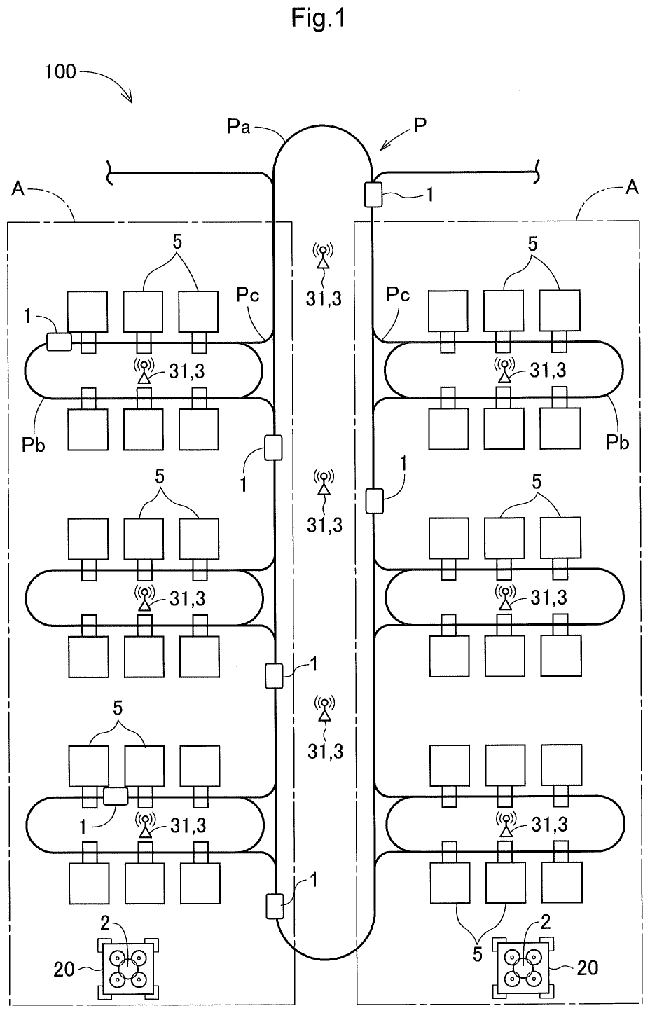

A transport facility 100 according to a first embodiment will be described below with reference to FIGS. 1 to 6. As shown in FIG. 1, the transport facility 100 includes at least one transport vehicle 1 and at least one movable object 2. In the present embodiment, the transport facility 100 includes multiple transport vehicles 1 and multiple movable objects 2.

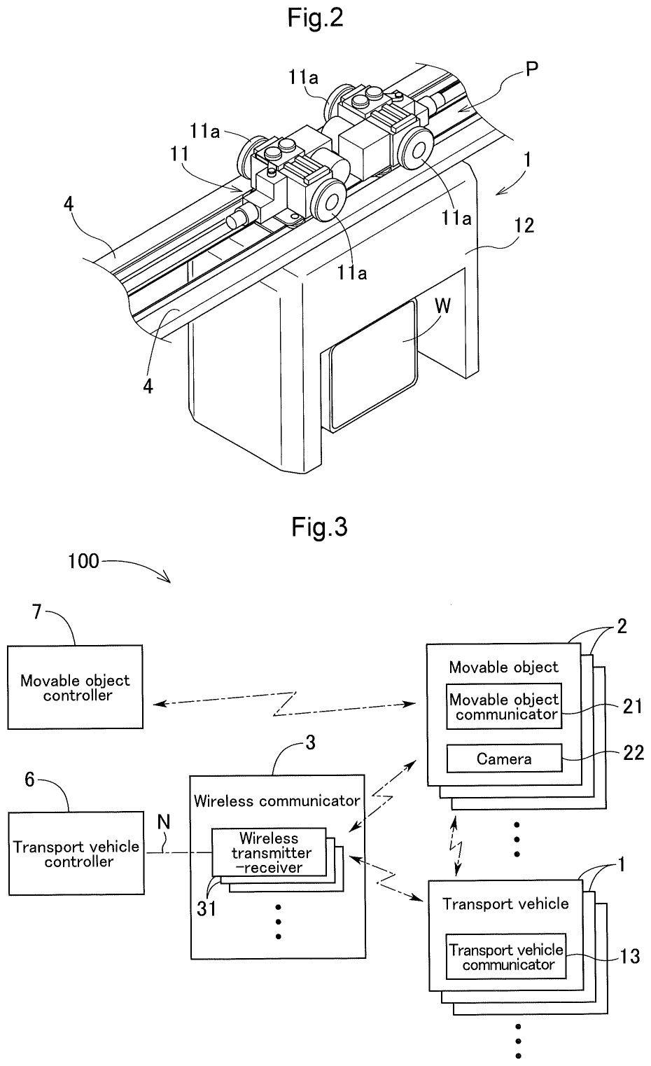

Each transport vehicle 1 transports a transport article W (refer to FIG. 2) along a movement path P. The transport article W is, for example, a front opening unified pod (FOUP) containing semiconductor wafers.

In the present embodiment, the movement path P includes a looped primary path Pa, multiple looped secondary paths Pb each extending through multiple processing devices 5, and multiple connecting paths Pc connecting the primary path Pa and the secondary paths Pb.

Each processing device 5 performs predetermined processing on the transport article W (or an object contained in the transport article W). For example, the transport vehicle 1 loads the transport article W to be processed in the processing device 5 into the processing device 5 and unloads the transport article W processed in the processing device 5 from the processing device 5.

The movable objects 2 move separately from the transport vehicles 1. In the present embodiment, the movable objects 2 are unmanned aerial vehicles. In other words, the movable objects 2 are movable on a path different from the movement path P. In the present example, each movable object 2 flies within a preset flight area A. In the present example, the transport facility 100 includes at least one flight area A to allow at least one movable object 2 to correspond to one flight area A. In the present example, the transport facility 100 includes standby units 20 at which the movable objects 2 as unmanned aerial vehicles depart, land, or are on standby after landing. The standby units 20 may include chargers for charging the batteries in the movable objects 2.

As shown in FIG. 2, the transport facility 100 in the present embodiment further includes rails 4 extending along the movement path P. The transport vehicles 1 travel on the rails 4. In the example shown in FIG. 2, the rails 4 as a pair are horizontally spaced from each other and hung from the ceiling. In other words, in the present example, the transport vehicles 1 are ceiling-hung transport vehicles.

In the present embodiment, each transport vehicle 1 includes a traveler 11 that travels along the movement path P and a body 12 connected to the traveler 11.

The traveler 11 includes travel wheels 11a that roll on the travel surfaces (upper surfaces in this example) of the rails 4. The travel wheels 11a are rotated by a travel driver (not shown), or for example, by an electric motor such as a servomotor.

The body 12 is disposed below the rails 4 and hung from the traveler 11. The body 12 includes a support and a lift (not shown). The support is supported on the traveler 11 to be lifted and lowered with respect to the traveler 11 and suspends the transport article W. The lift lifts and lowers the support.

In the example shown in FIG. 2, the transport vehicle 1 is a ceiling-hung transport vehicle that travels along the rails 4 hung from the ceiling. However, the transport vehicle 1 may be of any other type. For example, the transport vehicle 1 may be a tracked transport vehicle that travels along rails on a floor surface. The transport vehicle 1 may also be a trackless transport vehicle such as an automated guided vehicle (AGV) or an autonomous mobile robot (AMR). The transport vehicle 1 being a trackless transport vehicle travels along a virtual movement path P, instead of a physical movement path P that includes rails or other members. In this case, the movement path P is virtually defined to connect multiple detectable members such as two-dimensional codes or radio frequency (RF) tags installed on the floor surface. The movement path P may also be virtually defined based on a route calculated using recognition results of the surrounding environment, without such detectable members on the floor surface.

As shown in FIG. 3, the transport facility 100 in the present embodiment further includes a wireless communicator 3. The wireless communicator 3 performs wireless communication with the transport vehicles 1. In the present embodiment, the wireless communicator 3 includes multiple wireless transmitter-receivers 31 arranged in a distributed manner (refer also to FIG. 1). Each wireless transmitter-receiver 31 functions as an access point in wireless communication.

In the present embodiment, each transport vehicle 1 further includes a transport vehicle communicator 13 that performs wireless communication with the wireless communicator 3.

The transport vehicle communicator 13 functions as a wireless station that performs wireless communication with the wireless transmitter-receivers 31. The transport vehicle communicator 13 establishes a communication link with a wireless transmitter-receiver 31 (e.g., a wireless transmitter-receiver 31 having the highest radio field intensity) selected from the multiple wireless transmitter-receivers 31. The transport vehicle communicator 13 is then connected to and communicates with the selected wireless transmitter-receiver 31. While traveling, the transport vehicle 1 switches the wireless transmitter-receiver 31 with which the transport vehicle communicator 13 in the transport vehicle 1 establishes a communication link (performs roaming). For example, roaming is performed in response to the radio field intensity received from the connected wireless transmitter-receiver 31 being lower than or equal to a predetermined value.

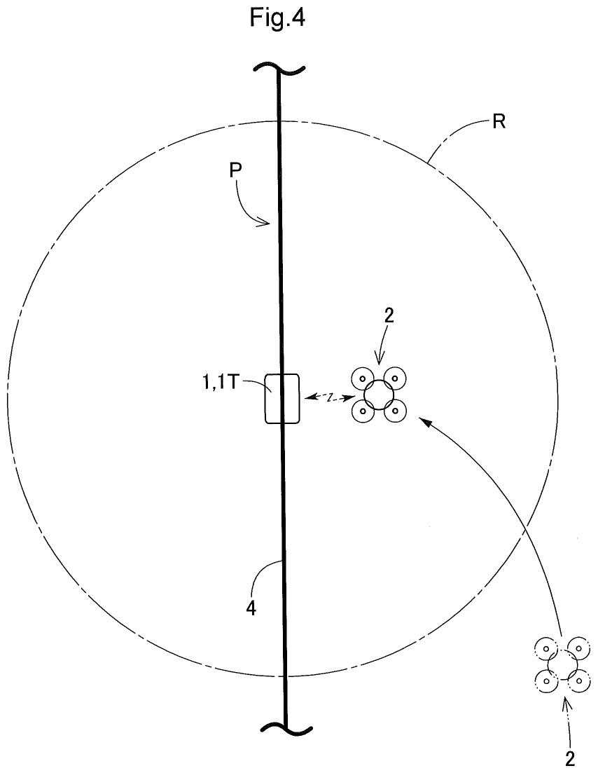

Each movable object 2 includes a movable object communicator 21. The movable object communicator 21 is a communication device that performs wireless communication with a transport vehicle 1 being within a communication range R (refer to FIG. 4). In the present embodiment, the movable object communicator 21 performs wireless communication with the transport vehicle communicator 13. In the present embodiment, the movable object communicator 21 can also perform wireless communication with the wireless transmitter-receivers 31. In the present application, wireless communication refers to communication performed under a predetermined wireless communication standard, such as Wi-Fi (registered trademark), Bluetooth (registered trademark), or ZigBee (registered trademark).

As shown in FIG. 3, the transport facility 100 includes a movable object controller 7. In the present embodiment, the transport facility 100 further includes a transport vehicle controller 6.

The transport vehicle controller 6 communicates with the transport vehicles 1 through the wireless communicator 3 to control the transport vehicles 1. In the present embodiment, the transport vehicle controller 6 is connected to the multiple wireless transmitter-receivers 31 with a communication network N. The communication network N may be wired, wireless, or a combination of both.

In the present embodiment, each transport vehicle 1 includes a controller (not shown) for controlling its operations (e.g., traveling and transfer of the transport article W). The transport vehicle controller 6 communicates with the transport vehicle communicator 13 in each transport vehicle 1 through the wireless communicator 3 to provide commands for the above operations to the controller in the transport vehicle 1.

In the present embodiment, the transport vehicle 1 identifies its current position. For example, information holders such as two-dimensional codes or RF tags are installed at multiple locations along the movement path P. Each information holder holds information indicating the position of the information holder. Each transport vehicle 1 includes a reader that reads the information held by the information holders and a distance detector (e.g., a rotary encoder) that detects the distance traveled by the transport vehicle 1. Each transport vehicle 1 identifies its current position based on the information read with the reader and the travel distance detected with the distance detector after the reader reads the information. In the present embodiment, the transport vehicle controller 6 obtains, from each transport vehicle 1, position information indicating the current position of the transport vehicle 1.

The movable object controller 7 controls the movable objects 2. In the present embodiment, each movable object 2 includes a controller (not shown) for controlling its operations (e.g., flying). The movable object controller 7 performs wireless communication with the movable object communicator 21 in each movable object 2 to provide commands for the above operations to the controller in the movable object 2. In the present embodiment, each movable object 2 identifies its current position. The movable object controller 7 then obtains, from each movable object 2, position information indicating the current position of the movable object 2.

When determining that any transport vehicle 1 is faulty, the movable object controller 7 performs a recovery process. For example, the movable object controller 7 determines whether any transport vehicle 1 is faulty based on the position information of the transport vehicles 1 obtained by the transport vehicle controller 6.

As shown in FIG. 4, in the recovery process, the movable object controller 7 causes any movable object 2 to be within the communication range R of a recovery target vehicle 1T, which is the transport vehicle 1 to be recovered. When any movable object 2 is already within the communication range R of the recovery target vehicle 1T, no movable object 2 may be moved. The movable object controller 7 then causes the movable object communicator 21 to transmit, to the recovery target vehicle 1T, a recovery command for recovering the recovery target vehicle 1T. In the communication range R, the movable object communicator 21 can perform wireless communication with the transport vehicle 1 (the transport vehicle communicator 13 in this example). The communication range R varies based on, for example, the structure of the transport vehicle communicator 13 or the movable object communicator 21, the type of wireless communication standard described above, or the presence of any obstacle.

In the present embodiment, the recovery command corresponds to a command transmitted from the transport vehicle controller 6 and not received by the transport vehicle 1 due to a communication failure through the wireless communicator 3. When, for example, a command for transferring the transport article W transmitted from the transport vehicle controller 6 is not received by the transport vehicle 1 due to a communication failure through the wireless communicator 3, the recovery command is the same as the command for transferring the transport article W. The recovery command may be a command for restarting the controller in the recovery target vehicle 1T. This structure increases the likelihood of recovery of the recovery target vehicle 1T when the fault in the recovery target vehicle 1T is caused by a malfunction of its controller.

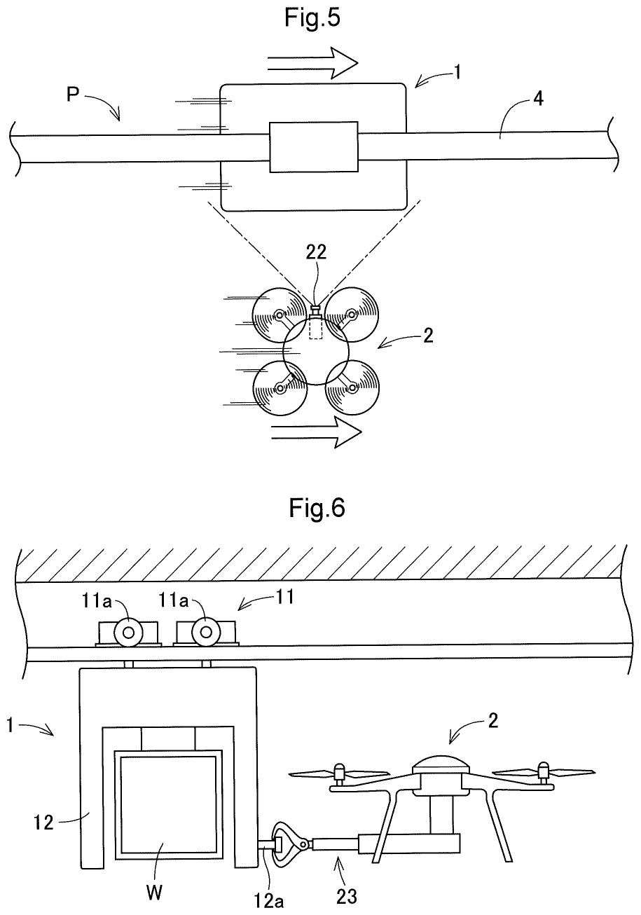

As shown in FIG. 5, the movable object controller 7 in the present embodiment performs a tracking process of causing the movable object 2 to track the transport vehicle 1 during movement of the transport vehicle 1. The movable object 2 monitors the state of the transport vehicle 1 while tracking the transport vehicle 1 in the tracking process. In the present application, tracking refers to moving at a speed equal to the speed of the transport vehicle 1 while maintaining the distance from the transport vehicle 1 within a predetermined range.

In the present embodiment, each movable object 2 further includes a camera 22. The camera 22 captures the moving transport vehicle 1 to obtain capture data such as images or videos. More specifically, in the present embodiment, monitoring the state of the transport vehicle 1 refers to capturing images of the transport vehicle 1 with the camera 22.

In the present embodiment, the movable object controller 7 uses the image data obtained with the camera 22 to determine whether each transport vehicle 1 is faulty. For example, the movable object controller 7 determines, based on the videos captured with the camera 22, whether the transport vehicle 1 has stopped unexpectedly or is generating abnormal noise while traveling. The camera 22 may be a high-speed camera. The movable object controller 7 may determine whether the travel wheels 11a of the transport vehicle 1 move appropriately based on the videos at a high frame rate obtained with the camera 22. The image data obtained with the camera 22 may be stored in a storage (not shown) included in the movable object 2 or in a storage (not shown) included in the movable object controller 7. The image data may be stored to, for example, analyze the cause of the fault in the transport vehicle 1.

As shown in FIG. 6, each movable object 2 in the present embodiment further includes a coupler 23 to be coupled to a transport vehicle 1. In response to the recovery target vehicle 1T remaining faulty after transmission of the recovery command to the recovery target vehicle 1T, the movable object controller 7 performs a towing process. In the towing process, the movable object controller 7 causes the movable object 2 to couple the coupler 23 to the recovery target vehicle 1T and to tow the recovery target vehicle 1T to move the recovery target vehicle 1T to a retreat position.

In the present embodiment, the coupler 23 includes a robotic arm. In the present embodiment, the body 12 in each transport vehicle 1 includes a grippable part 12a. The robotic arm in the coupler 23 grips the grippable part 12a, and thereby the movable object 2 is coupled to the transport vehicle 1.

In the present embodiment, the power transmission path between the travel wheels 11a and the travel driver in each transport vehicle 1 includes a brake (not shown), or a negative brake such as a power-off brake, for releasing the travel wheels 11a from the braking state in response to a release signal being input. The body 12 in each transport vehicle 1 also includes, on its side surface, a terminal for receiving the release signal.

In the present embodiment, the terminal and the grippable part 12a are disposed on the same side surface of the body 12 (on one side surface or on both side surfaces in a direction parallel to the movement path P). The robotic arm in the coupler 23 can grip the grippable part 12a with the release signal input into the terminal. In the towing process, the movable object 2 moves the recovery target vehicle 1T along the rails 4 to the retreat position with the travel wheels 11a of the recovery target vehicle 1T being rollable.

### 2. Second Embodiment

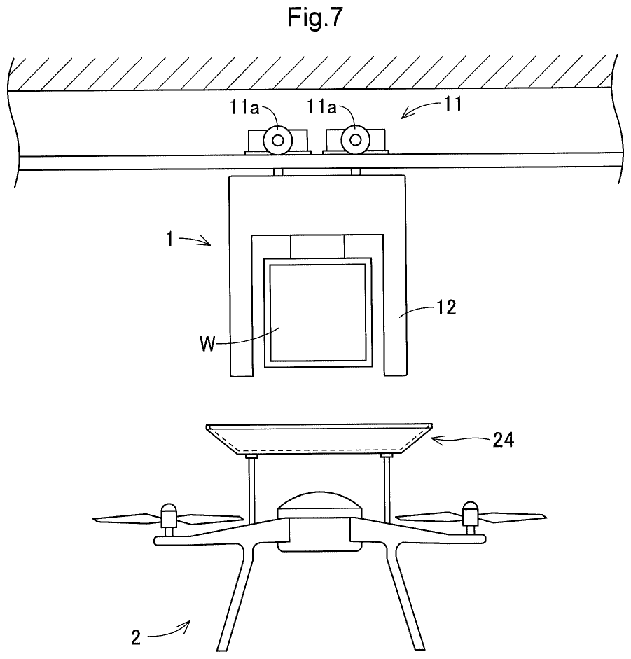

A transport facility 100 according to a second embodiment will be described below with reference to FIG. 7. In the present embodiment, each movable object 2 includes a holder 24 in place of the coupler 23, unlike in the first embodiment. The embodiment will be described below focusing on the differences from the first embodiment. The components not described below are the same as those in the first embodiment.

In the present embodiment, as shown in FIG. 7, in response to the recovery target vehicle 1T remaining faulty after transmission of the recovery command to the recovery target vehicle 1T, the movable object controller 7 performs an alternative transport process. In the alternative transport process, the movable object controller 7 causes the movable object 2 to hold the transport article W being transported by the recovery target vehicle 1T with the holder 24 and to transport the transport article W to a destination. The movable object controller 7 can obtain information indicating the destination of the transport article W from the transport vehicle controller 6.

In the present embodiment, the holder 24 includes a tray on which the transport article W can be placed. In the present embodiment, the movable object 2 is moved to have the tray in the holder 24 placed below the transport article W suspended from the support in the recovery target vehicle 1T. The transport article W is then released from the support in the recovery target vehicle 1T to be placed on the tray in the holder 24.

### 3. Other Embodiments

(1) In the above embodiment, the movable objects 2 are unmanned aerial vehicles that are movable on a path different from the movement path P for the transport vehicles 1. In some embodiments, the movable objects 2 may move on the movement path P for the transport vehicles 1 (or may be, for example, vehicles that travel on the rails 4). Such movable objects 2 may transport, similarly to the transport vehicles 1, transport articles W in normal operations with no recovery target vehicle 1T, or may be dedicated to transmitting the recovery command to the recovery target vehicle 1T without transporting transport articles W.

(2) In the above embodiment, the movable object controller 7 provides commands to the controller in each movable object 2. In some embodiments, for example, the movable object controller 7 may be incorporated in each of the multiple movable objects 2 to allow the corresponding movable object 2 to operate independently of the others or cooperate with the others.

(3) In the first embodiment, the coupler 23 includes the robotic arm. In some embodiments, for example, the coupler 23 may include a hook that can be hooked on a hook receiver on the body 12 of each transport vehicle 1, a wire coupled to the hook, and a winder that can wind up the wire. In some embodiments, the coupler 23 may include an adhering member such as a magnet that can adhere to an adhering member receiver on the body 12 of each transport vehicle 1, a wire coupled to the adhering member, and a winder that can wind up the wire.

(4) In the second embodiment, the holder 24 includes the tray on which the transport article W can be placed. In some embodiments, for example, the holder 24 may include a gripper that can grip the transport article W. The holder 24 may hold the transport article W being transported by the recovery target vehicle 1T automatically as controlled by the movable object controller 7 controlling the movable object 2 or in response to an operator's manual operation.

(5) The structure described in each of the above embodiments may be combined with any other structures described in the other embodiments unless any contradiction arises. For other structures as well, the embodiments described herein are merely illustrative in all aspects. Thus, the embodiments described herein may be modified variously as appropriate without departing from the spirit and scope of the disclosure.

### 4. Overview of Present Embodiment

An overview of the transport facility described above is provided below.

A transport facility includes a transport vehicle that transports a transport article along a movement path, a movable object including a communication device that performs wireless communication with the transport vehicle being within a communication range and being movable separately from the transport vehicle, and a movable object controller that controls the movable object. The movable object controller causes, in response to determining that the transport vehicle is faulty, the movable object to be within the communication range of the transport vehicle and causes the communication device to transmit, to the transport vehicle, a recovery command for recovery of the transport vehicle.

In this structure, the movable object moves separately from the transport vehicle, and can thus appropriately move into the communication range of any faulty transport vehicle. This allows the movable object to transmit the recovery command to the transport vehicle, with lower likelihood of being affected by, for example, the communication environment surrounding the transport vehicle. Thus, the faulty transport vehicle can be recovered with higher possibility.

The movable object controller may cause the movable object to track the transport vehicle during movement of the transport vehicle.

The movable object may monitor a state of the transport vehicle while tracking the transport vehicle.

In this structure, the information obtained from monitoring the state of the transport vehicle can be used to analyze the cause of a fault in the transport vehicle. Thus, the recovery command appropriately responding to the cause of the fault can be transmitted to the transport vehicle.

The movable object may further include a coupler to be coupled to the transport vehicle.

In response to the transport vehicle remaining faulty after transmission of the recovery command to the transport vehicle, the movable object controller may couple the coupler to the transport vehicle, cause the movable object to tow the transport vehicle, and move the transport vehicle to a retreat position.

In this structure, the transport vehicle remaining faulty after transmission of the recovery command can be moved to the retreat position. Thus, the faulty transport vehicle is less likely to obstruct movement of any other transport vehicles. The structure can reduce lower transport efficiency in the transport facility.

The transport facility may further include a wireless communicator that performs wireless communication with the transport vehicle, and a transport vehicle controller that communicates with the transport vehicle through the wireless communicator to control the transport vehicle.

The recovery command may correspond to a command transmitted from the transport vehicle controller and not received by the transport vehicle due to a communication failure through the wireless communicator.

In this structure, when a command transmitted from the transport vehicle controller is not received by the transport vehicle due to a communication failure through the wireless communicator, the movable object can transmit the recovery command corresponding to the command to correct the fault in the transport vehicle.

The movable object may further include a holder that holds the transport article.

In response to the transport vehicle remaining faulty after transmission of the recovery command to the transport vehicle, the movable object controller may cause the holder to hold the transport article being transported by the transport vehicle and cause the movable object to transport the transport article to a destination.

In this structure, when the transport vehicle remains faulty after transmission of the recovery command to the transport vehicle, the transport article being transported by the transport vehicle can be transported to a destination.

The transport facility may further include a rail extending along the movement path.

The transport vehicle may travel on the rail.

The movable object may be an unmanned aerial vehicle.

In this structure, the movable object can fly in the air independently of the shape of the movement path for the transport vehicle. Thus, the movable object away from a faulty transport vehicle can promptly move into the communication range of the transport vehicle. This allows the movable object to promptly transmit the recovery command to the transport vehicle.

This structure also causes the movable object tracking the transport vehicle to appropriately track the transport vehicle.

### INDUSTRIAL APPLICABILITY

The technique according to one or more embodiments of the disclosure is applicable to a transport facility including a transport vehicle that transports a transport article along a movement path.

What is claimed is:

1. A transport facility, comprising:
a transport vehicle configured to transport a transport article along a movement path;
a movable object comprising a communication device configured to perform wireless communication with the transport vehicle being within a communication range, the movable object movable separately from the transport vehicle; and
a movable object controller configured to control the movable object, and
wherein the movable object controller is configured to cause, in response to determining that the transport vehicle is faulty, the movable object to be within the communication range of the transport vehicle and cause the communication device to transmit, to the transport vehicle, a recovery command for recovery of the transport vehicle.

2. The transport facility according to claim 1, wherein:
the movable object controller causes the movable object to track the transport vehicle during movement of the transport vehicle, and
the movable object monitors a state of the transport vehicle while tracking the transport vehicle.

3. The transport facility according to claim 1, wherein:
the movable object further comprises a coupler to be coupled to the transport vehicle, and
in response to the transport vehicle remaining faulty after transmission of the recovery command to the transport vehicle, the movable object controller causes the movable object to couple the coupler to the transport vehicle and to tow the transport vehicle to move the transport vehicle to a retreat position.

4. The transport facility according to claim 1, further comprising:
a wireless communicator configured to perform wireless communication with the transport vehicle; and
a transport vehicle controller configured to communicate with the transport vehicle through the wireless communicator to control the transport vehicle, and
wherein the recovery command corresponds to a command transmitted from the transport vehicle controller and not received by the transport vehicle due to a communication failure through the wireless communicator.

5. The transport facility according to claim 1, wherein:
the movable object further comprises a holder configured to hold the transport article, and
in response to the transport vehicle remaining faulty after transmission of the recovery command to the transport vehicle, the movable object controller causes the movable object to hold the transport article being transported by the transport vehicle with the holder and to transport the transport article to a destination.

6. The transport facility according to claim 1, further comprising:
a rail extending along the movement path,
wherein the transport vehicle travels on the rail, and
wherein the movable object is an unmanned aerial vehicle.
